(19) United States
(12) Patent Application Publication
(10) Pub. No.: US 2013/0149844 A1
(43) Pub. Date: Jun. 13, 2013

(54) METHOD OF GROWING ZINC OXIDE NANOWIRE

(71) Applicants: Yong Hee Kim, Daejeon (KR); Nam Seob Baek, Daejeon (KR); Sang Don Jung, Daejeon (KR)

(72) Inventors: Yong Hee Kim, Daejeon (KR); Nam Seob Baek, Daejeon (KR); Sang Don Jung, Daejeon (KR)

(73) Assignee: Electronics and Telecommunications Research Institute, Daejeon (KR)

(21) Appl. No.: 13/601,843

(22) Filed: Aug. 31, 2012

(30) Foreign Application Priority Data
Dec. 12, 2011 (KR) 10-2011-0133023

(51) Int. Cl. H01L 21/20; B82Y 40/00

(52) U.S. Cl. 438/478; 257/E21.09; 977/762

(57) ABSTRACT

Methods of growing a zinc oxide nanowire are provided. According to the method, developing a photoresist layer and etching a zinc oxide seed layer may be successively performed using a tetramethyl ammonium hydroxide aqueous solution. Thus, change of solutions may not be required, such that the number of processes may be reduced.

### CROSS-REFERENCE TO RELATED APPLICATIONS

This U.S. non-provisional patent application claims priority under 35 U.S.C. §119 to Korean Patent Application No. 10-2011-0133023, filed on Dec. 12, 2011, the entirety of which is incorporated by reference herein.

### BACKGROUND

The inventive concept relates to methods of growing a zinc oxide (ZnO) nanowire and, more particularly, to methods of growing a zinc oxide nanowire using etching of a zinc oxide seed layer.

Zinc oxide may have high transmittance, high refractive index, and strong piezo-electric property in a visible light region. Thus, the zinc oxide may optical properties similar to those of gallium nitride (GaN) used as materials of a light emitting diode (LED) and a laser diode (LD). Particularly, the zinc oxide has exciting binding energy three times greater than that of gallium nitride, such that the zinc oxide may induce high efficiency light emitting and may have low threshold energy in stimulated spontaneous emission generated by a laser pumping. Due to the above properties, the zinc oxide may be variously used as photonic crystals, optical modulator waveguides, varistors, transparent electrodes of solar cells, surface acoustic wave filters, light emitting devices such as a laser diode, flat displays, field emission displays (FED), photo-detectors, gas sensors, and/or anti-ultraviolet films.

The zinc oxide may be easily formed into a nanowire or a nanostick of a one-dimensional shape. A manufacture of a zinc oxide nano structure regularly arranged may be an important technique in fields of an optical device, an electrical device, and/or a sensor. A technique used in the manufacture of the nano structure having a regular pattern may relate to a semiconductor manufacture technique. Thus, the manufacture of the zinc oxide nano structure may require complicated manufacture processes. In a conventional art, the patterns of the zinc oxide nano structure may be formed by a method using a PDMS stamp, a method using a dry etching process, or a method using a wet etching process using a chemical material. The wet etching method of the above methods may be simplest. The wet etching of the zinc oxide may use an acid such as a hydrochloric acid or a sulfuric acid, and a chemical material such as NH₄Cl or FeCl₃.

### SUMMARY

Embodiments of the inventive concept may provide methods of more simply growing a zinc oxide nanowire.

In one aspect, a method of growing a zinc oxide nanowire may include: forming a zinc oxide seed layer on a substrate; forming a photoresist layer on the zinc oxide seed layer; pattering the photoresist layer; patterning the zinc oxide seed layer by etching the zinc oxide seed layer using the patterned photoresist layer; removing the photoresist layer on the patterned zinc oxide seed layer; and growing a zinc oxide nanowire on the patterned zinc oxide seed layer. Patterning the photoresist layer and patterning the zinc oxide seed layer may be successively performed.

In some embodiments, patterning the photoresist layer and patterning the zinc oxide seed layer may be successively performed using a tetramethyl ammonium hydroxide aqueous solution.

In other embodiments, a concentration of tetramethyl ammonium hydroxide may have a range of about 1% to about 3% in the tetramethyl ammonium hydroxide aqueous solution.

In still other embodiments, a thickness of the zinc oxide seed layer may have a range of about 300 Å to about 1 μm.

In yet other embodiments, forming the zinc oxide seed layer may include: spin-coating a mixture solution of methanol, 2-methoxyethanol, and zinc acetate on the substrate.

In yet still other embodiments, the photoresist layer may be a positive photoresist layer.

In yet still other embodiments, the zinc oxide nanowire may be grown on the patterned zinc oxide seed layer by a hydrothermal synthesis method, a chemical vapor deposition method, or a physical vapor deposition method.

In yet still other embodiments, the hydrothermal synthesis method may include a process reacting the patterned zinc oxide seed layer with a mixture of zinc nitrate and hexamethylenetetramine

### BRIEF DESCRIPTION OF THE DRAWINGS

The inventive concept will become more apparent in view of the attached drawings and accompanying detailed description.

FIGS. 1 to 6 are perspective views illustrating a method of growing a zinc oxide nanowire according to embodiments of the inventive concept; and

FIG. 7 is a scanning electron microscope (SEM) photograph of a zinc oxide nanowire according to embodiments of the inventive concept.

### DETAILED DESCRIPTION OF THE EMBODIMENTS

The inventive concept will now be described more fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. In the drawings, embodiments of the inventive concept are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the inventive concept. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concept.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concept explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

A method of growing a zinc oxide nanowire according to embodiments of the inventive concept may include forming a zinc oxide seed layer on a substrate, coating a photoresist on the substrate having the zinc oxide seed layer, exposing the photoresist by a photomask having a desired pattern, successively performing development of the photoresist and etching of the zinc oxide seed layer by a tetramethyl ammonium hydroxide aqueous solution, removing the photoresist on the patterned zinc oxide seed layer, and growing a zinc oxide nanowire on the patterned zinc oxide seed layer.

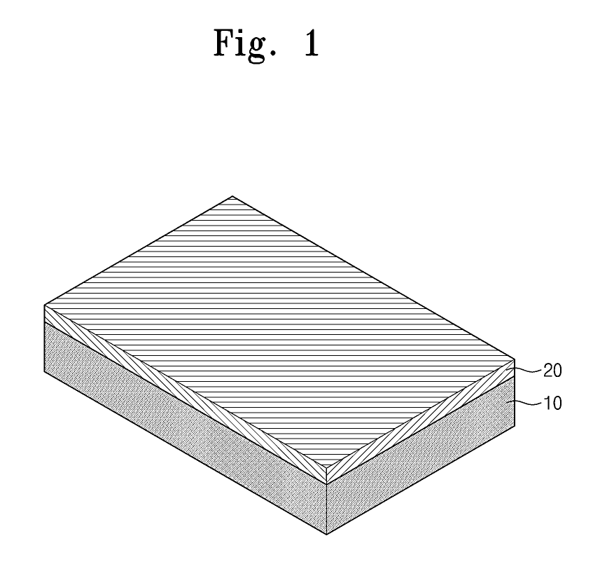

FIGS. 1 to 6 are perspective views illustrating a method of growing a zinc oxide nanowire according to embodiments of the inventive concept.

Referring to FIG. 1, a zinc oxide seed layer 20 may be formed on a substrate 10.

The substrate 10 may be an indium-tin-oxide (ITO) substrate, a silicon substrate, a plastic substrate, or a glass substrate. A mixture solution may be spin-coated on the substrate 10 of which impurities are removed. The mixture solution may include a mixture solvent of methanol and 2-methoxyethanol, and a zinc acetate solution of 0.005M concentration mixed in the mixture solvent. The spin coating process may be repeatedly performed three times. In this case, after each of the spin coating processes is performed, the substrate 10 may be heated at a temperature of about 110 degrees Celsius. After the last spin coating process is performed, the substrate 10 may be heated at a temperature of about 350 degrees Celsius to form the zinc oxide seed layer 20. The zinc oxide seed layer may have a thickness within a range of about 300 Å to about 1 μm.

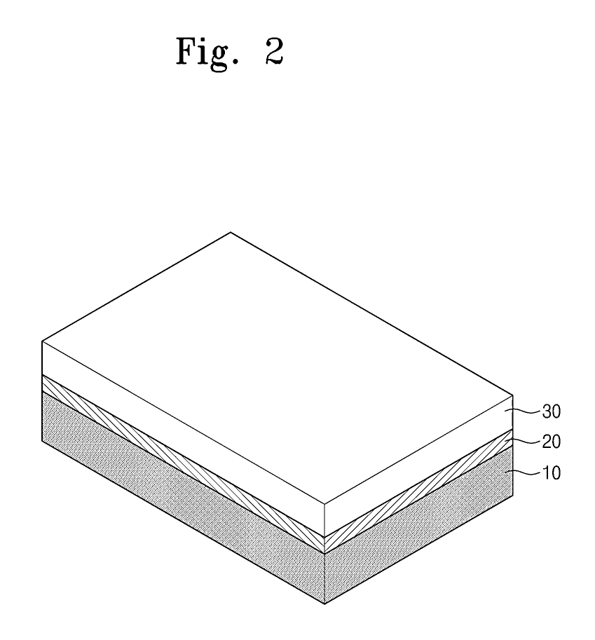

Referring to FIG. 2, a photoresist layer 30 may be formed on the zinc oxide seed layer 20. The photoresist layer 30 may be a positive photoresist layer. A thickness of the photoresist layer 30 may be within a range of about 1.1 μm to about 1.9 μm. After the photoresist layer 30 is formed on the substrate 10, a soft bake process may be performed. Water and an organic solvent may be removed from the photoresist layer 30 by the soft bake process.

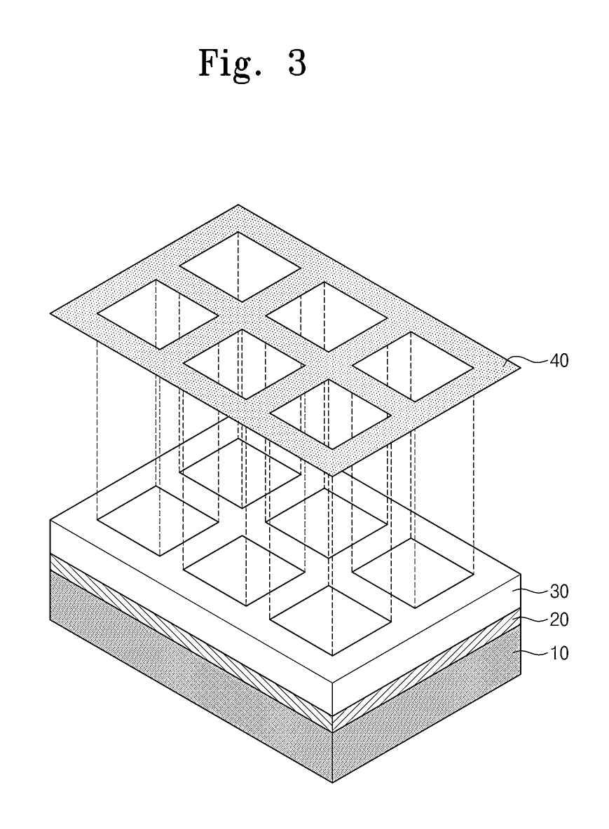

Referring to FIG. 3, exposing the photoresist layer 30 may be performed. After a photomask 40 including a desired pattern is disposed over the photoresist layer 30, ultraviolet rays may be irradiated to the photoresist layer 30 through the photomask 40. After the irradiation of the ultraviolet rays, the photoresist layer 30 may be heated at a temperature of about 110 degrees Celsius.

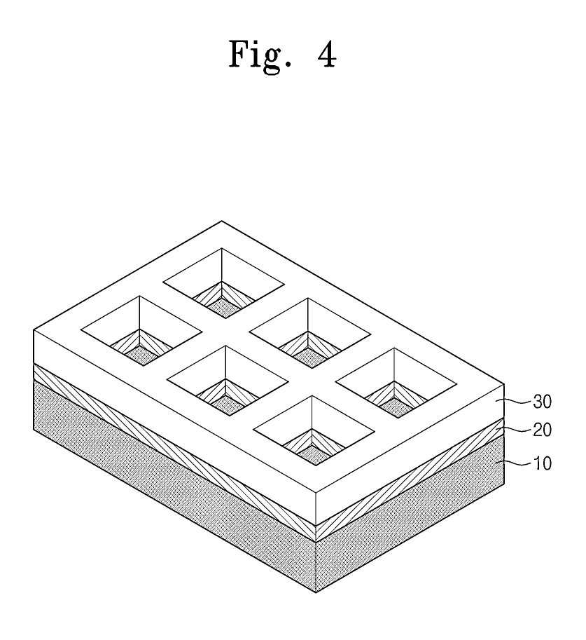

Referring to FIG. 4, after the exposure of the photoresist layer 30, developing the photoresist layer 30 and etching the zinc oxide seed layer 20 may be performed. The substrate 10 having the exposed photoresist layer 30 may soak in a tetramethyl ammonium hydroxide aqueous solution. A concentration of tetramethyl ammonium hydroxide may have a range of about 1% to about 3% in the tetramethyl ammonium hydroxide aqueous solution. However, the inventive concept is not limited to the above concentration of the tetramethyl ammonium hydroxide aqueous solution. Due to the tetramethyl ammonium hydroxide aqueous solution, developing the photoresist layer 30 and etching the zinc oxide seed layer may be successively performed. The zinc oxide seed layer 20 may be patterned by the etching of the zinc oxide seed layer 20.

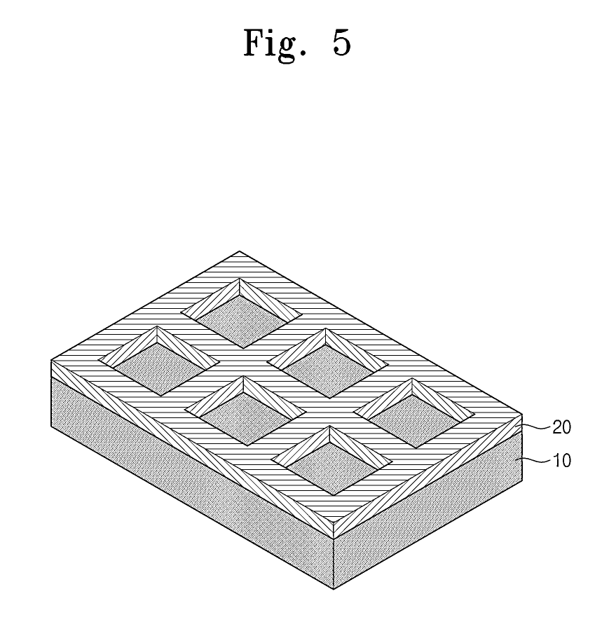

Referring to FIG. 5, the substrate 10 having the patterned zinc oxide seed layer 20 may be cleaned by acetone. Ultrasonic waves may be used during the cleaning of the substrate 10. The photoresist layer 30 on the patterned zinc oxide seed layer 20 may be removed by the cleaning using the acetone.

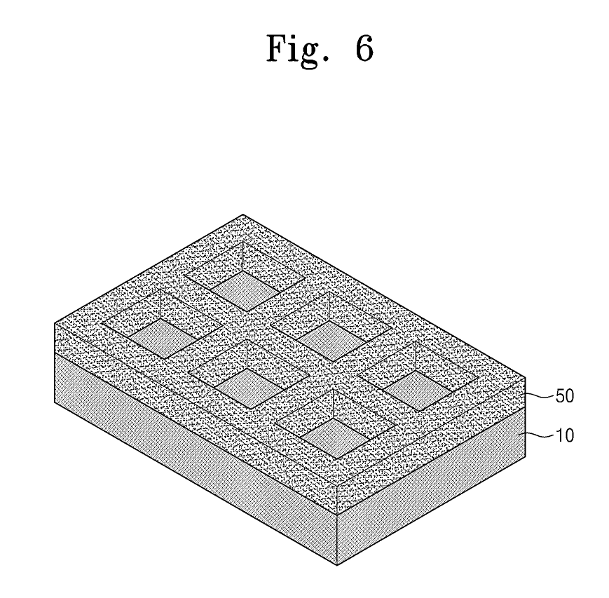

Referring to FIG. 6, a zinc oxide nanowire 50 may be selective grown on the patterned zinc oxide seed layer 20. The zinc oxide nanowire 50 may be grown by a hydrothermal synthesis method, a chemical vapor deposition method, or a physical vapor deposition method. In the growth of the zinc oxide nanowire 50 by the hydrothermal synthesis method, the substrate 10 including the patterned zinc oxide seed layer 20 may be soaked in a solution including zinc nitrate of about 0.025M and hexamethylenetetramine of about 0.025M. Thus, the zinc oxide nanowire 50 may be grown on the patterned zinc oxide seed layer 20. A reacting temperature during the growth of the zinc oxide nanowire 50 may be about 95 degrees Celsius. The substrate 10 on which the zinc oxide nanowire 50 is grown may be soaked in deionized water and then be cleaned by ultrasonic waves. After impurities are removed from the substrate 10 by the cleaning process, the substrate 10 may be dried by nitrogen.

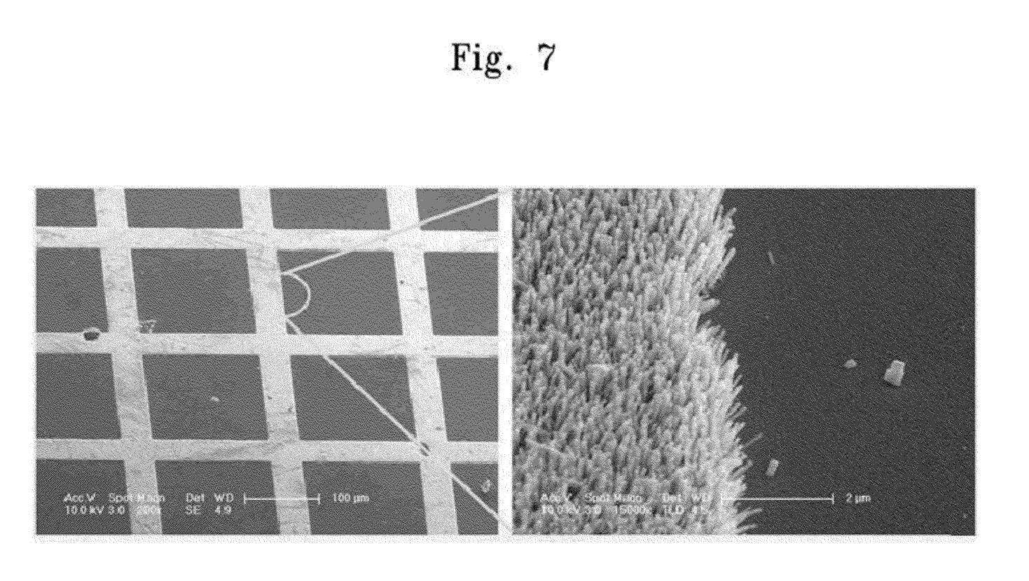

FIG. 7 is a scanning electron microscope (SEM) photograph of a zinc oxide nanowire according to embodiments of the inventive concept. As can be seen from FIG. 7, the zinc oxide nanowire is grown on only the zinc oxide seed layer.

According to embodiments of the inventive concept, developing the photoresist layer and etching the zinc oxide seed layer may be successively performed using the tetramethyl ammonium hydroxide aqueous solution. Thus, the number of processes may be reduced.

While the inventive concept has been described with reference to example embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

What is claimed is:

1. A method of growing a zinc oxide nanowire, comprising:
forming a zinc oxide seed layer on a substrate;
forming a photoresist layer on the zinc oxide seed layer;
pattering the photoresist layer;
patterning the zinc oxide seed layer by etching the zinc oxide seed layer using the patterned photoresist layer;
removing the photoresist layer on the patterned zinc oxide seed layer; and
growing a zinc oxide nanowire on the patterned zinc oxide seed layer,
wherein patterning the photoresist layer and patterning the zinc oxide seed layer are successively performed.

2. The method of claim of claim 1, wherein patterning the photoresist layer and patterning the zinc oxide seed layer are successively performed using a tetramethyl ammonium hydroxide aqueous solution.

3. The method of claim 2, wherein a concentration of tetramethyl ammonium hydroxide has a range of about 1% to about 3% in the tetramethyl ammonium hydroxide aqueous solution.

4. The method of claim 1, wherein a thickness of the zinc oxide seed layer has a range of about 300 Å to about 1 μm.

5. The method of claim 1, wherein forming the zinc oxide seed layer comprises:
spin-coating a mixture solution of methanol, 2-methoxyethanol, and zinc acetate on the substrate.

6. The method of claim 1, wherein the photoresist layer is a positive photoresist layer.

7. The method of claim 1, wherein the zinc oxide nanowire is grown on the patterned zinc oxide seed layer by a hydrothermal synthesis method, a chemical vapor deposition method, or a physical vapor deposition method.

8. The method of claim 7, wherein the hydrothermal synthesis method includes a process reacting the patterned zinc oxide seed layer with a mixture of zinc nitrate and hexamethylenetetramine.
